(19) United States
(12) Patent Application Publication
(10) Pub. No.: US 2014/0042444 A1
(43) Pub. Date: Feb. 13, 2014

(54) PIXEL STRUCTURE AND FABRICATING METHOD OF PIXEL STRUCTURE

(71) Applicant: AU OPTRONICS CORPORATION, Hsinchu (TW)

(72) Inventors: Kuo-Yu Huang, Hsinchu County (TW); Wei-Lun Chang, Hsinchu City (TW); Maw-Song Chen, Taipei City (TW)

(73) Assignee: AU OPTRONICS CORPORATION, Hsinchu (TW)

(21) Appl. No.: 13/689,775

(22) Filed: Nov. 30, 2012

(30) Foreign Application Priority Data
Aug. 9, 2012 (TW) 101128839

(51) Int. Cl. H01L 29/786; H01L 29/66

(52) U.S. Cl. CPC H01L 29/78654; H01L 29/6675; H01L 29/78663
USPC 257/59; 438/34; 257/72

(57) ABSTRACT

A pixel structure and a fabricating method thereof are provided. An insulating layer and a planar layer are formed on an electrode. The planar layer has a first opening. A conductive layer is formed on the planar layer and filled into the first opening. A patterned photoresist layer having an etching opening is formed. A wet etching process employing the patterned photoresist layer as a mask is performed on the conductive layer to remove the conductive layer disposed above the electrode via the etching opening and etch laterally the conductive layer below the patterned photoresist layer, to form a patterned conductive layer having a second opening. A dry etching process employing the patterned photoresist layer as a mask is performed on the insulating layer to remove the insulating layer disposed above the electrode via the etching opening, to form a patterned insulating layer having a third opening.

### CROSS-REFERENCE TO RELATED APPLICATION

This application claims the priority benefit of Taiwan application serial no. 101128839, filed on Aug. 9, 2012. The entirety of the above-mentioned patent application is hereby incorporated by reference herein and made a part of this specification.

### BACKGROUND

1. Technical Field

The invention relates to a pixel structure and a fabricating method of a pixel structure, and more particularly, to a pixel structure and a fabricating method of a pixel structure with high resolution.

2. Related Art

Generally speaking, a pixel structure of a high resolution display includes a thin film transistor and a pixel electrode electrically connected to the thin film transistor. The thin film transistor is disposed on a substrate, wherein the thin film transistor includes a gate electrode, a gate dielectric layer, a channel layer, a source electrode and a drain electrode. In general, a thicker planar layer is applied to improve the planarization, such that the liquid crystal may rotate more smoothly. The planar layer is disposed on the substrate, and has a first opening exposing a part of the drain electrode. A capacitor electrode is disposed on the planar layer and filled into the first opening. Further, the capacitor electrode has a second opening exposing a part of the drain electrode. The patterned insulating layer is disposed on the capacitor electrode to cover the capacitor electrode, and has a third opening exposing a part of the drain electrode. The pixel electrode is disposed on the patterned insulating layer and electrically connected to the drain electrode via the third opening.

Multiple photo-masks may usually be applied in the fabrication of pixel structures, so as to form a first patterned metal layer including a scan line and a gate electrode, a second patterned metal layer including a data line, a source electrode and a drain electrode, a patterned semiconductor layer including a channel layer, a planar layer having a first opening, a first patterned conductive layer having a second opening and served as a capacitor electrode, a patterned insulating layer having a third opening and a patterned conductive layer served as a pixel electrode on a substrate. The process of fabricating the pixel structure with use of multiple photo-masks may result in misalignment to a certain extent, thereby causing an offset to exist among each film layer of the pixel structure having high resolution. For example, the capacitor electrode formed by the first patterned conductive layer may be deviated towards the edge of the first opening of the planar layer, and therefore it is possible that the capacitor electrode may slide into the first opening due to the inconsistency of photo-resist thickness. In this way, the short circuit is occurred on the capacitor electrode and the drain electrode. In order to avoid the circumstances described above to occur, the method such as over exposure must be applied to increase the distance between the capacitor electrode and the first opening of the planar layer. As a result, the critical dimension may not be easily controlled, and the resolution of the pixel structure may be difficult to improve.

### SUMMARY

Accordingly, the invention is directed to a fabricating method of a pixel structure, so as to avoid the short circuit occurring on a first electrode and a first patterned conductive layer and reduce the required number of photo-masks.

The invention is further directed to a pixel structure, so as to have high resolution and a high capacitor area, and have superior element characteristics and display quality.

The invention provides a fabricating method of a pixel structure. A thin film transistor is formed on a substrate, wherein the thin film transistor includes a first electrode. A first insulating layer is formed on the substrate to cover the first electrode. A planar layer is formed on the substrate to cover the first insulating layer and have a first opening, wherein the first opening exposes the first insulating layer located above the first electrode. A first conductive layer is formed on the planar layer, and the first conductive layer is filled into the first opening. A patterned photoresist layer is formed on the first conductive layer, wherein the patterned photoresist layer has an etching opening, and the etching opening exposes the first conductive layer located above the first electrode. A wet etching process is performed on the first conductive layer. The wet etching process is employed the patterned photoresist layer as a mask to remove the first conductive layer located above the first electrode via the etching opening and etch laterally a part of the first conductive layer located below the patterned photoresist layer, so as to form a first patterned conductive layer, wherein the first patterned conductive layer has a second opening. The second opening is located within the first opening and exposes the first insulating layer located above the first electrode. A dry etching process is performed on the first insulating layer. The dry etching process is employed the patterned photoresist layer as a mask to remove the first insulating layer located above the first electrode via the etching opening, so as to form a first patterned insulating layer, wherein the first patterned insulating layer has a third opening exposing the first electrode. The third opening is smaller than the second opening, and the third opening is self-aligned within the second opening. The patterned photoresist layer is removed. A second patterned insulating layer is formed on the first patterned conductive layer. The second patterned insulating layer covers the first patterned conductive layer and the part of the first patterned insulating layer exposed within the second opening. The second patterned insulating layer has a fourth opening. The fourth opening is located within the third opening and exposes a part of the first electrode. A second patterned conductive layer is formed on the second patterned insulating layer, wherein the second patterned conductive layer is electrically connected to the first electrode via the fourth opening.

The invention further provides a pixel structure that is disposed on a substrate. The pixel structure includes a thin film transistor, a planar layer, a first patterned conductive layer, a first patterned insulating layer, a second patterned insulating layer and a second patterned conductive layer. The thin film transistor is disposed on the substrate and includes a first electrode. The planar layer is disposed on the substrate, wherein the planar layer has a first opening that exposes a part of the first electrode. The first patterned conductive layer is disposed on the planar layer and filled into the first opening. The first patterned conductive layer has a second opening, wherein the second opening is located within the first opening and exposes the part of the first electrode. The first patterned insulating layer is disposed between the substrate and the planar layer and covers the thin film transistor. The first patterned insulating layer has a third opening, wherein the third opening is smaller than the second opening, and the third opening is self-aligned within the second opening and exposes the first electrode. The second patterned insulating layer is disposed on the first patterned conductive layer. The second patterned insulating layer covers the first patterned conductive layer and a part of the first patterned insulating layer exposed within the second opening. The second patterned insulating layer has a fourth opening. The fourth opening is located within the third opening and exposes the part of the first electrode. The second patterned conductive layer is electrically connected to the first electrode via the fourth opening.

Based on the above descriptions, in the fabricating method of the pixel structure of the invention, the same photo-mask is applied to perform the wet etching process on the first conductive layer to form the first patterned conductive layer having the second opening, and to perform the dry etching process on the first insulating layer to form the first patterned insulating layer having the third opening. Thus, the third opening is smaller than the second opening, and the third opening is self-aligned within the second opening. In this way, the occurrence of short circuits on the first electrode and the first patterned conductive layer may be avoided, the required number of photo-masks may also be reduced, and therefore the resolution and the aperture ratio of the pixel structure may be improved.

In order to make the aforementioned and other features and advantages of the invention more comprehensible, the invention is further described in detail in the following with reference to the embodiments and the accompanying drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A through FIG. 1J are schematic cross-sectional views illustrating a process of a fabricating method of a pixel structure according to an embodiment of the invention.

FIG. 2A is a schematic top view illustrating the pixel structure of FIG. 1J.

FIG. 2B is a schematic enlarged view illustrating a first through a fourth openings in FIG. 2A.

FIG. 3A through FIG. 3D are schematic cross-sectional views illustrating a process of a fan-out circuit according to an embodiment of the invention.

FIG. 4 is a schematic top view illustrating FIG. 3D, wherein FIG. 3D is a schematic cross-sectional view taken along a line C-C′ depicted in FIG. 4.

### DESCRIPTION OF THE EMBODIMENTS

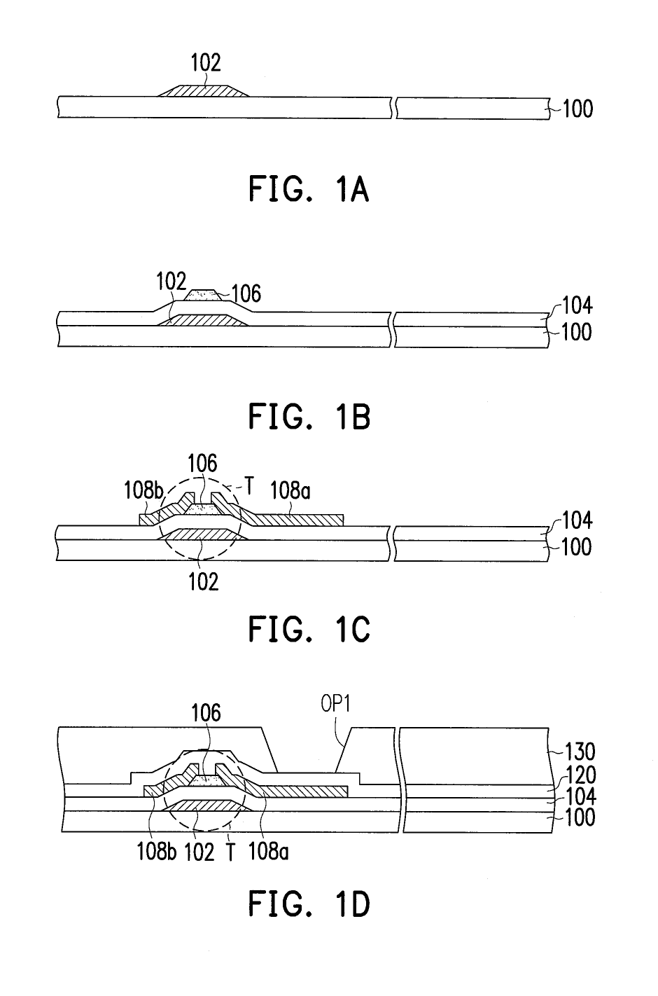

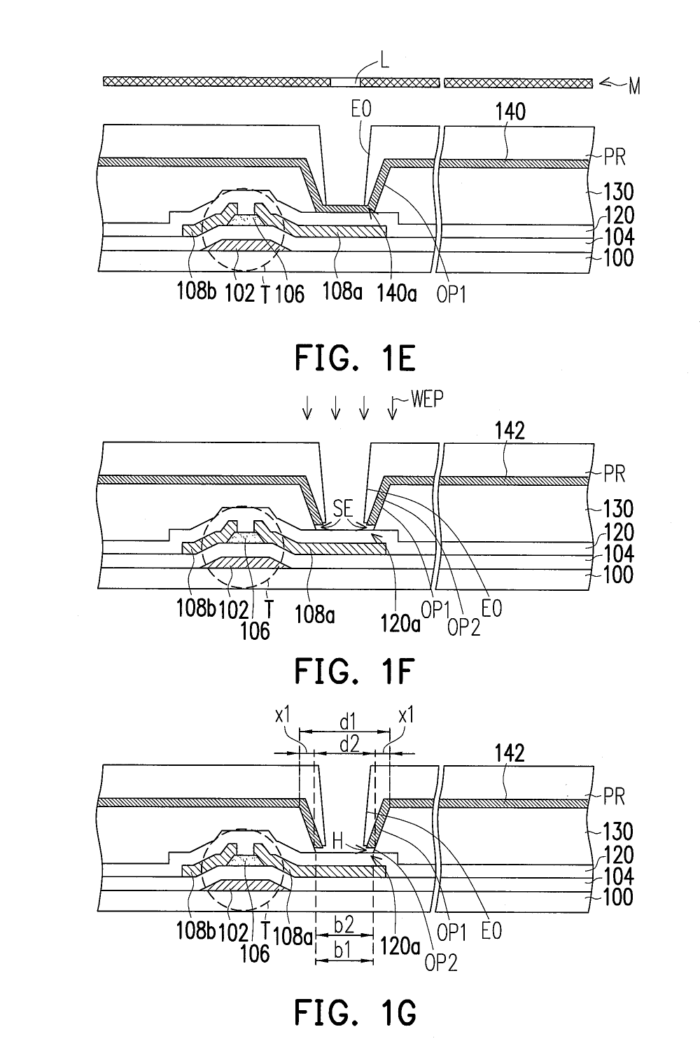

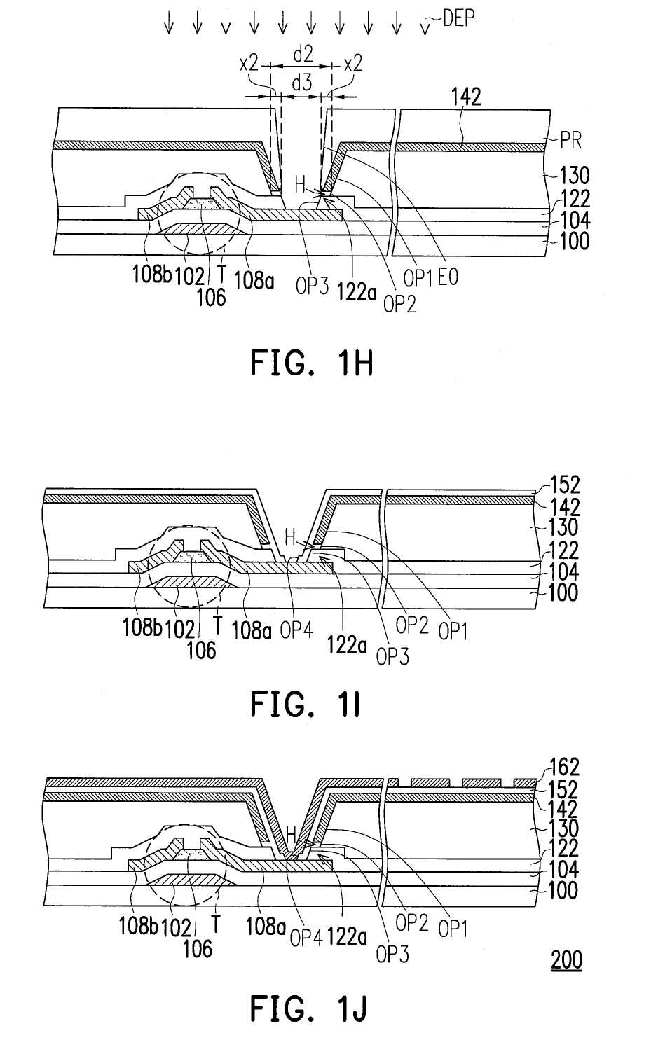

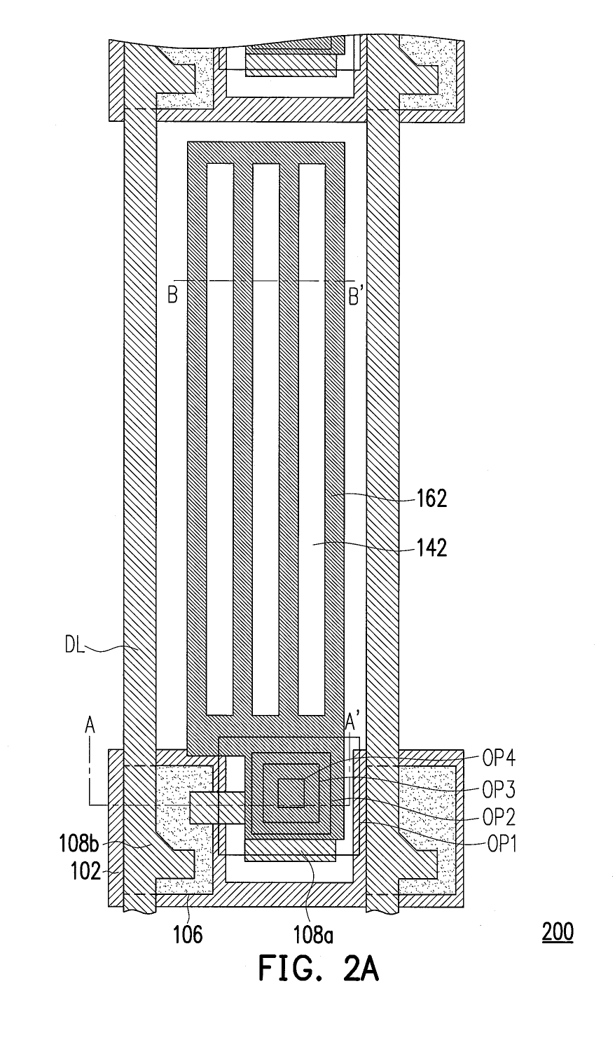

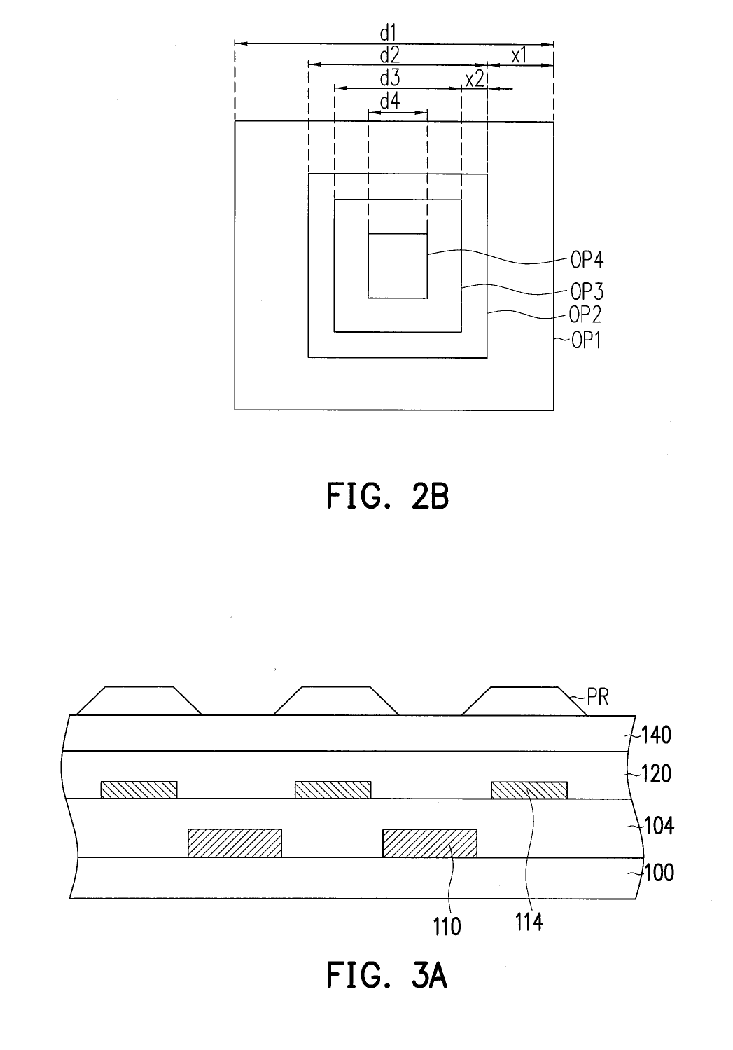

FIG. 1A through FIG. 1J are schematic cross-sectional views illustrating a process of a fabricating method of a pixel structure according to an embodiment of the invention, and FIG. 2A is a schematic top view illustrating the pixel structure of FIG. 1J, wherein the left-hand portion and the right-hand portion of the separating line are respectively the cross-sectional view taken along lines A-A′ and B-B′ depicted in FIG. 2A. Moreover, FIG. 2B is a schematic enlarged view illustrating a first through a fourth openings in FIG. 2A. Firstly, referring to FIG. 1A through FIG. 1D, a thin film transistor T is formed on a substrate 100, and the thin film transistor T includes a first electrode 108a. In the embodiment, the substrate 100, for instance, includes an active region and a peripheral region (not shown), wherein the steps described in FIG. 1A through FIG. 1J are performed on the active region of the substrate 100. The thin film transistor T is, for instance, a bottom-gate type thin film transistor and the fabricating method thereof, for instance, includes the following steps. Certainly, in another embodiment, the thin film transistor T may also be a top-gate type thin film transistor or a coplanar type thin film transistor, but the invention is not limited thereto.

Referring to FIG. 1A, firstly, the bottom-gate type thin film transistor is exemplified to describe herein. A gate electrode 102 is formed on the substrate 100. Referring to FIG. 1B, next, a gate dielectric layer 104 is formed on the substrate 100, and the gate dielectric layer 104 covers the gate electrode 102. Then, a channel layer 106 is formed on the gate dielectric layer 104 and aligned to the gate electrode 102. In the embodiment, the material of the channel layer 105 is a semiconductor material, such as amorphous silicon, polysilicon, monocrystalline silicon, indium-gallium-zinc oxide (IGZO), metal oxide semiconductor material and organic semiconductor material etc.

Referring to FIG. 1C, next, the first electrode 108a and a second electrode 108b are formed on the two sides of the channel layer 106. The first electrode 108a and the second electrode 108b are electrically connected to the channel layer 106. In the embodiment, the first electrode 108a is, for instance, a drain electrode, and the second electrode 108b is, for instance, a source electrode, but the invention is not limited thereto. In other words, any one of the first electrode 108a and the second electrode 108b is, for instance, a drain electrode and another one is, for instance, a source electrode.

Referring to FIG. 1D, then, a first insulating layer 120 is formed on the substrate 100 and covers the first electrode 108a. In the embodiment, the material of the first insulating layer 120, for instance, includes silicon nitride, silicon oxide or silicon oxynitride. Next, a planar layer 130 is formed on the substrate 100 to cover the first insulating layer 120 and have a first opening OP1, wherein the first opening OP1 exposes the first insulating layer 120 located above the first electrode 108a. In the embodiment, the planar layer 130, for instance, includes an organic material layer, and the material of the planar layer 130, for instance, includes polyimide, polyethylene terephthalate (PET), poly methylmethacrylate (PMMA), poly carbonate (PC), poly(phenylene oxide) (PPO), polyoxy methylene (POM), polystyrene (PS), benzocyclobutene (BCB), polybenzazole (PBO) and spin on glass (SOG), cyclic olefin copolymers (COC) etc.

Referring to FIG. 1E, next, a first conductive layer 140 is formed on the planar layer 130, and the first conductive layer 140 is filled into the first opening OP 1. In the embodiment, the material of the first conductive layer 140, for instance, includes a transparent conductive material, such as indium tin oxide (ITO), indium zinc oxide (IZO), and aluminum zinc oxide (AZO) etc.

Then, a photoresist layer (not shown) is formed on the first conductive layer 140, and a photo-mask M is provided above the substrate 100, wherein the photo-mask M, for instance, has a light-transmissive region L. Next, the photoresist layer is patterned by using the photo-mask M, so as to form a patterned photoresist layer PR on the first conductive layer 140. The patterned photoresist layer PR has an etching opening EO, and the etching opening EO exposes the first conductive layer 140 located above the first electrode 108a. In the embodiment, since the thickness of the planar layer 130 is thicker, in order to expose the bottom of the etching opening EO completely in the exposure step, the photoresist layer is patterned by using the photo-mask M in the over-exposure manner, such that the size of the etching opening EO formed is larger than the size of the light-transmissive region L of the photo-mask M. Accordingly, affect causing from the residue on the etching process of the first conductive layer 140 is avoided, and the residue of the first conductive layer 140 is also avoided. For example, the horizontal distance between an edge of the light-transmissive region L and the corresponding bottom edge of the etching opening EO is, for instance, 0.5 um.

Referring to FIG. 1F and FIG. 1G concurrently, next, an isotropic etching process such as a wet etching process is performed on the first conductive layer 140. The wet etching process WEP is employed the patterned photoresist layer as a mask to remove the first conductive layer 140 located above the first electrode 108a via the etching opening EO and etch laterally SE a part of the first conductive layer 140a (see FIG. 1E) located below the patterned photoresist layer PR, so as to form a first patterned conductive layer 142. As shown in FIG. 1G, the first patterned conductive layer 142 has a second opening OP2. The second opening OP2 is located within the first opening OP1 and exposes the first insulating layer 120 located above the first electrode 108a. Namely, etching laterally SE is to remove the part of the first conductive layer 140a located below the patterned photoresist layer PR, and for instance, to further remove parts of the first conductive layer 140, such that the first patterned conductive layer 142 may shrink inwards to a certain extent and have lateral holes H. In other words, the second opening OP2 of the first patterned conductive layer 142 further includes the lateral holes H exposing parts of the first insulating layer 120a. In the embodiment, an etchant applied in the wet etching process WEP is, for instance, oxalic acid ((COOH)₂), ferric salt solution (FeCl₃+HCl) and aqua regia etc., but the invention is not limited thereto. The first opening OP1, for instance, has a first top diameter d1 and a first bottom diameter b1. The second opening OP2, for instance, has a second top diameter d2 and a second bottom diameter b2. The second top diameter d2 is, for instance, smaller than the first top diameter d1. In the embodiment, the second bottom diameter b2 is, for instance, equal to the first bottom diameter b1, but the invention is not limited thereto. The size of the holes H may be varied depending on the state where the wet etching process removes the first conductive layer 140, therefore, the second bottom diameter b2 may be smaller than or equal to the first bottom diameter b1. The size of the first top diameter d1 is, for example, ranged from 5 μm to 10 μm, and the second top diameter d2 is, for instance, ranged from 3 μm to 8 μm. In the embodiment, the horizontal distance×1 between the top edge of the first opening OP1 and the top edge of the second opening OP2 is, for instance, ranged from 0.01 um to 10 um, and more preferably ranged from 0.5 um to 3.0 um. The first patterned conductive layer 142 such as a mesh electrode covers the planar layer 130 completely. Additionally, the first conductive layer 142 can also be partially removed in accordance with the required pattern. The first patterned conductive layer 142 may be served as a counter electrode or a common electrode.

Referring to FIG. 1H, then, an anisotropic etching process such as a dry etching process DEP is performed on the first insulating layer 120. The dry etching process DEP is employed a patterned photoresist layer PR as the mask to remove the first insulating layer 120 located above the first electrode 108a via the etching opening EO, so as to form a first patterned insulating layer 122, wherein the first patterned insulating layer 122 has a third opening OP3 exposing the first electrode 108a and located within the second opening OP2. Since the second opening OP2 and the third opening OP3 are formed by using the same patterned photoresist layer PR as the mask, the third opening OP3 is smaller than the second opening OP2 and the third opening OP3 is self-aligned within the second opening OP2, so that the horizontal distances between the edge of second opening OP2 and the edge of third opening OP3 at any location are about equidistant. In the embodiment, the etchant utilized in the dry etching process DEP includes etching gases such as hexafluoroethylene (SF6) or carbon tetrafluoride (CF4) etc., but the invention is not limited thereto. The top diameter d3 of the third opening OP3 is, for instance, substantially smaller than the top diameter d2 of the second opening OP2. The horizontal distance×2 between the top edge of the second opening OP2 and the top edge of the third opening OP3 is, for instance, ranged from 0.01 μm to 3 μm, and more preferably ranged from 0.1 μm to 1.0 μm. The wet etching process WEP is capable of controlling the etching rate precisely, therefore, the edge of the second opening OP2 and the edge of the third opening OP3 may be relatively close, and the issue on the offset in the process between the second opening OP2 and the third opening OP3 is no need to be concerned.

Referring to FIG. 1I, next, the patterned photoresist layer PR is removed. Then, a second patterned insulating layer 152 is formed on the first patterned conductive layer 142, and the material thereof is, for instance, silicon oxide, silicon nitride or silicon oxynitride etc. The second patterned insulating layer 152 covers the first patterned conductive layer 142 and the part of the first insulating layer 122 exposed by the second opening OP2. The second patterned insulating layer 152 has a fourth opening OP4, wherein the fourth opening OP4 is located within the third opening OP3 and exposes the part of the first electrode 108a. In the embodiment, the second patterned insulating layer 152 is, for instance, filled into the holes H exposing the part of the first insulating layer 122.

Referring to FIG. 1J, then, a second patterned conductive layer 162 is formed on the second patterned insulating layer 152. The second patterned conductive layer 162 as a pixel electrode is electrically connected to the first electrode 108a via the fourth opening OP4. The material of the second patterned conductive layer 162, for instance, includes a transparent conductive material, such as indium tin oxide, indium zinc oxide and aluminium zinc oxide etc. In the embodiment, the second patterned insulating layer 152, for instance, covers the first patterned conductive layer 142 and the part of the first insulating layer 122 exposed by the second opening OP2, so as to electrically insulate the first patterned conductive layer 142 from the first electrode 108a and the second patterned conductive layer 162. Namely, the second patterned insulating layer 152 formed on the first patterned conductive layer 142 and filled into the holes H, substantially coats the first patterned conductive layer 142 completely, such that the first patterned conductive layer 142 is not exposed, so as to electrically insulate the first patterned conductive layer 142 from the first electrode 108a and the second patterned conductive layer 162.

Referring to FIG. 1J, FIG. 2A and FIG. 2B concurrently, in the embodiment, the pixel structure 200 is disposed on the substrate 100. The pixel structure 200 includes the thin film transistor T, the planar layer 130, the first patterned conductive layer 142, the first patterned insulating layer 122, the second patterned insulating layer 152 and the second patterned conductive layer 162. The thin film transistor T is disposed on the substrate 100 and includes the first electrode 108a. The planar layer 130 is disposed on the substrate 100. The planar layer 130 has the first opening OP1 that exposes a part of the first electrode 108a. The first patterned conductive layer 142 is disposed on the planar layer 130 and filled into the first opening OP1. The first patterned conductive layer 142 has the second opening OP2, wherein the second opening OP2 is located within the first opening OP1 and exposes the part of the first electrode 108a. The first patterned insulating layer 122 is disposed between the substrate 100 and the planar layer 130 and covers the thin film transistor T. The first patterned insulating layer 122 has the third opening OP3, where the third opening OP3 is smaller than the second opening OP2. The third opening OP3 is self-aligned within the second opening OP2 and exposes the first electrode 108a. The second patterned insulating layer 152 is disposed on the first patterned conductive layer 142. The second patterned insulating layer 152 covers the first patterned conductive layer 142 and the part of the first patterned insulating layer 122 exposed by the second opening OP2. The second patterned insulating layer 152 has the fourth opening OP4. The fourth opening OP4 is located within the third opening OP3 and exposes the part of the first electrode 108a. The second patterned conductive layer 162 is electrically connected to the first electrode 108a via the fourth opening OP4.

In the embodiment, the thin film transistor T, for instance, includes the gate electrode 102, the gate dielectric layer 104, the channel layer 106, the first electrode 108a and the second electrode 108b. The gate electrode 102 is disposed on the substrate 100. The gate dielectric layer 104 is disposed on the substrate 100 and covers the gate electrode 102. The channel layer 106 is disposed on the gate dielectric layer 104 and aligned to the gate electrode 102. The first electrode 108a and the second electrode 108b are disposed on the two sides of the channel layer 106, and electrically connected to the channel layer 106. In the embodiment, the second electrode 108b is, for instance, electrically connected to a data line DL.

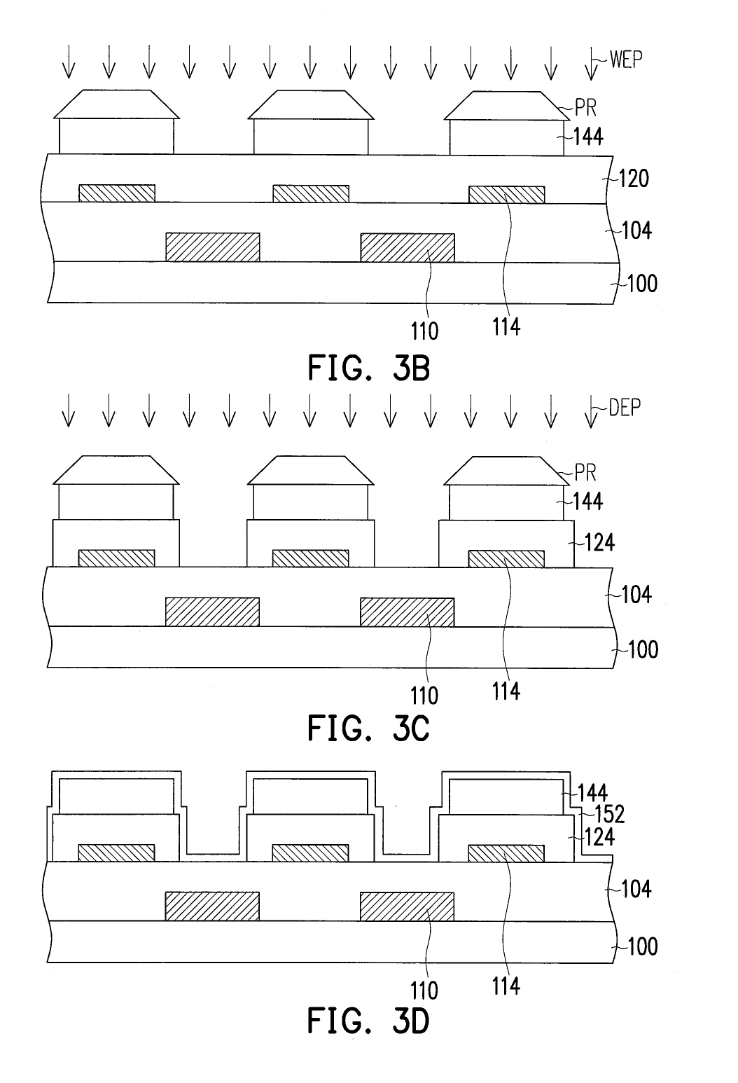

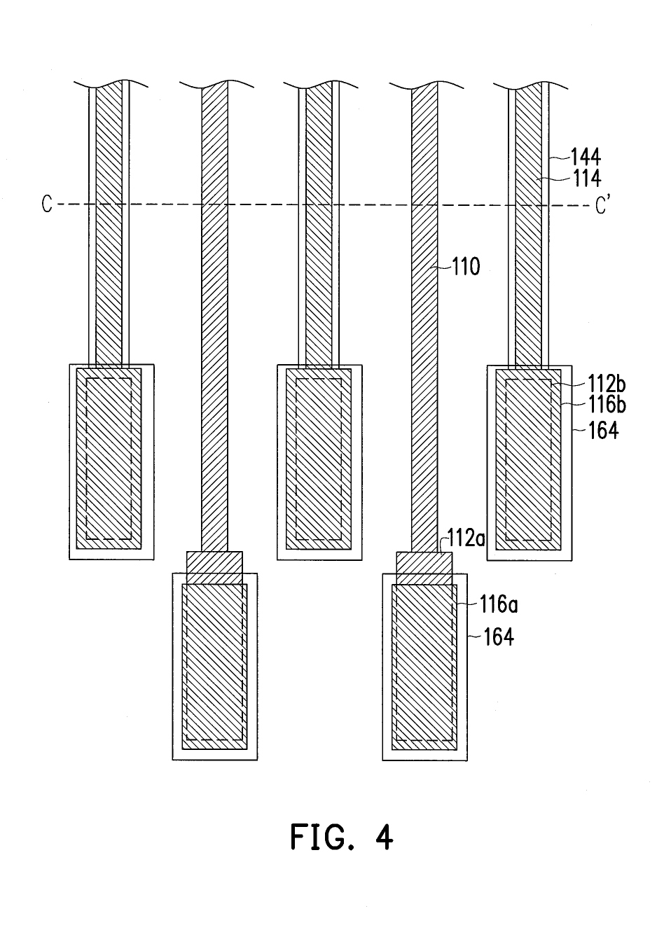

In the embodiment, the fabricating method of the pixel structure, for instance, further includes the fabrication of the double layered fan-out circuit in the fan out region of the periphery, which is described in detail below. FIG. 3A through FIG. 3D are schematic cross-sectional views illustrating a process of a fan-out circuit according to an embodiment of the invention, and FIG. 4 is a schematic top view illustrating FIG. 3D, wherein FIG. 3D is a schematic cross-sectional view taken along a line C-C′ depicted in FIG. 4. Referring to FIG. 3A, firstly, a plurality of first wires 110 are formed on a substrate 100. In the embodiment, the first wires 110 are, for instance, formed together with a gate electrode 102. Next, a gate dielectric layer 104 is formed on the first wires 110. Then, a plurality of second wires 114 are formed on the gate dielectric layer 104, wherein the first wires 110 and the second wires 114 are alternately disposed on the substrate 100. In the embodiment, the second wires 114 are, for instance, formed together with the first electrode 108a and the second electrode 108b. In the embodiment, the fabricating method further includes forming a plurality of first pads 112a, 112b and a plurality of second pads 116a, 116b on the substrate 100. The first pads 112a are electrically connected to the first wires 110, and the first pads 112a are, for instance, substantially integrally formed with the first wires 110. One of the second pads 116a is correspondingly disposed above each of the first pads 112a and electrically connected to the first pad 112a. One of the second pads 116b is correspondingly disposed above each of the first pads 112b and electrically connected to the first pad 112b. Wherein, the second pads 116b are electrically connected to the second wires 114, and the second pads 116b are, for instance, substantially integrally formed with the second wires 114.

Next, a first insulating layer 120 and a first conductive layer 140 as described above are formed sequentially on the second wires 114. Then, a patterned photoresist layer PR is formed on the first conductive layer 140 by using the aforementioned photo-mask M, and the patterned photoresist layer PR is correspondingly disposed above each of the second wires 114.

Referring to FIG. 3B, next, while a first patterned conductive layer 142 is formed by the wet etching process WEP described-above, a plurality of first conductive pattern blocks 144 are also formed by the wet etching process WEP, and each of the first conductive pattern blocks 144 is correspondingly disposed above one of the second wires 114. In another embodiment, the first conductive pattern blocks 144 may also be disposed above the first wires 110, to further protect the first wires 110.

Referring to FIG. 3C, then, while a first patterned insulating layer 122 is formed by the dry etching process DEP described-above, a plurality of first insulating pattern blocks 124 are also formed by the dry etching process DEP, and each of the first insulating pattern blocks 124 is disposed below one of the first conductive pattern block 144.

Referring to FIG. 3D, next, the patterned photoresist layer PR is removed. Then, a second patterned insulating layer 152 is formed on the first conductive pattern blocks 144, and the second patterned insulating layer 152 covers the first conductive pattern blocks 144 and the first insulating pattern blocks 124. Afterward, while a second patterned conductive layer 162 is formed, a plurality of second conductive pattern blocks 164 are formed, and each of the second conductive pattern blocks 164 is correspondingly disposed above each of the second pads 116a, 116b.

In the embodiment, the pixel structure 200, for instance, further includes the plurality of first wires 110, the gate dielectric layer 104, the plurality of second wires 114, the plurality of first insulating pattern blocks 124 and the plurality of first conductive pattern blocks 144. The first wires 110 are disposed on the substrate 100. The gate dielectric layer 104 is disposed on the first wires 110 and covers the first wires 110. The second wires 114 are disposed on the gate dielectric layer 104, wherein the first wires 110 and the second wires 114 are alternately disposed on the substrate 100. Each of the first insulating pattern blocks 124 is disposed on one of the second wires 122. Each of the first conductive pattern blocks 144 is disposed on one of the first insulating pattern blocks 124. In the embodiment, the first conductive pattern blocks 144 and the first patterned conductive layer 142 are, for instance, made of the same layer. The first insulating pattern blocks 124 and the first patterned insulating layer 122 are, for instance, made of the same layer.

In the embodiment, the same photo-mask M is applied to perform the wet etching process WEP on the first conductive layer 140 to form the first patterned conductive layer 142 having the second opening OP2, and to perform the dry etching process DEP on the first insulating layer 120 to form the first patterned insulating layer 122 having the third opening OP3. Since the wet etching process WEP is an anisotropic etching and the dry etching process DEP is an isotropic etching, in the case of applying the same photo-mask M, the third opening OP3 is smaller than the second opening OP2, and the third opening OP3 is self-aligned within the second opening OP2. In addition, since the second opening OP2 of the first patterned conductive layer 142 and the third opening OP3 of the first patterned insulating layer 122 are formed in the self-alignment manner, the horizontal distances between the top edge of the second opening OP2 and the top edge of the third opening OP3 at any location are about the same, for instance, ranged from 0.01 μm˜3.0 μm. In this way, the overlapping of the second opening OP2 and the third opening OP3 caused by the offset in the process may be avoided, thereby avoiding the short circuit on the first patterned conductive layer 142 and the first electrode 108a. In the pixel structure with high resolution, the sizes of the first opening OP1, the second opening OP2, the third opening OP3 and the fourth opening OP4 may be reduced significantly, and it is no need to consider the issue on the offset between the second opening OP2 and the third opening OP3. The area within the first opening OP1 may be further utilized, such that the overlapping area of the first patterned conductive layer 142 and the second patterned conductive layer 162 is increased, thereby enhancing the capacitor area and improving the display quality.

On the other hand, since the first patterned conductive layer 142 and the first patterned insulating layer 122 are applied the same photo-mask to pattern, the required number of photo-masks may be reduced to cut down the fabrication cost of pixel structures. Furthermore, since the horizontal distance between the top edge of the second opening OP2 and the top edge of the third opening OP3 may be reduced, the fabrication of the first patterned conductive layer 142 is more flexible in design, thereby improving the aperture ratio and the resolution of the pixel structure. In addition, the wet etching process WEP and the dry etching process DEP utilized in the fabricating method of the pixel structure of the embodiments may be combined with the current process such as the fan-out circuit, the double layered circuit etc., therefore, the fabricating steps for the pixel structure may not be changed significantly, and such processes are adapted to fabricate the display panel with the slim border design.

In light of the foregoing, in the invention, only one photo-mask is applied to perform the wet etching process on the first conductive layer to form the first patterned conductive layer having the second opening, and to perform the dry etching process on the first insulating layer to form the first patterned insulating layer having the third opening. Since the wet etching process performs laterally etching and the dry etching process performs isotropic etching, with use of the same photo-mask, the third opening is self-aligned within the second opening, the third opening is smaller than the second opening, and the horizontal distances between the top edge of the second opening and the top edge of the third opening at any location are about the same. In this way, the overlapping of the second opening and the third opening caused by the offset in the process may be avoided, thereby avoiding the short circuit on the first patterned conductive layer and the first electrode.

On the other hand, since the first patterned conductive layer and the first patterned insulating layer are applied the same photo-mask for patterning, the required number of photo-masks may be reduced to cut down the fabrication cost of pixel structures. More particularly, since the horizontal distance between the top edge of the second opening and the top edge of the third opening may be reduced and the short circuit may be avoided on the first patterned conductive layer and the first electrode, the fabrication of the first patterned conductive layer is more flexible in design, thereby improving the aperture ratio and the resolution of the pixel structure. In addition, the wet etching process and the dry etching process utilized in the fabricating method of the pixel structure of the embodiments may be combined with the current process such as the fan-out circuit, the double layered circuit etc., therefore, the fabricating steps for the pixel structure may not be changed significantly.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fabricating method of a pixel structure, comprising:
forming a thin film transistor on a substrate, wherein the thin film transistor comprises a first electrode;
forming a first insulating layer on the substrate to cover the first electrode;
forming a planar layer on the substrate to cover the first insulating layer and have a first opening, wherein the first opening exposes the first insulating layer located above the first electrode;
forming a first conductive layer on the planar layer to fill into the first opening;
forming a patterned photoresist layer on the first conductive layer, wherein the patterned photoresist layer has an etching opening, and the etching opening exposes the first conductive layer located above the first electrode;
performing a wet etching process on the first conductive layer, wherein the wet etching process is employed the patterned photoresist layer as a mask to remove the first conductive layer located above the first electrode via the etching opening and etch laterally a part of the first conductive layer located below the patterned photoresist layer, so as to form a first patterned conductive layer, the first patterned conductive layer has a second opening, the second opening is located within the first opening and exposes the first insulating layer located above the first electrode;
performing a dry etching process on the first insulating layer, wherein the dry etching process is employed the patterned photoresist layer as the mask to remove the first insulating layer located above the first electrode via the etching opening, so as to form a first patterned insulating layer, wherein the first patterned insulating layer has a third opening exposing the first electrode, the third opening is smaller than the second opening, and the third opening is self-aligned within the second opening;
removing the patterned photoresist layer;
forming a second patterned insulating layer on the first patterned conductive layer, wherein the second patterned insulating layer covers the first patterned conductive layer and the part of the first patterned insulating layer exposed by the second opening, the second patterned insulating layer has a fourth opening, the fourth opening is located within the third opening and exposes a part of the first electrode; and
forming a second patterned conductive layer on the second patterned insulating layer, where the second patterned conductive layer is electrically connected to the first electrode via the fourth opening.

2. The fabricating method of the pixel structure as claimed in claim 1, wherein the first electrode comprises a drain electrode.

3. The fabricating method of the pixel structure as claimed in claim 1, wherein the planar layer comprises an organic material layer.

4. The fabricating method of the pixel structure as claimed in claim 1, wherein the first opening has a first top diameter, the second opening has a second top diameter, and the second top diameter is smaller than the first top diameter.

5. The fabricating method of the pixel structure as claimed in claim 1, wherein the first opening has a first bottom diameter, the second opening has a second bottom diameter, and the second bottom diameter is larger than or equal to the first bottom diameter.

6. The fabricating method of the pixel structure as claimed in claim 1, wherein a horizontal distance between a top edge of the first opening and a top edge of the second opening is ranged from 0.01 μm to 10 μm.

7. The fabricating method of the pixel structure as claimed in claim 1, wherein the second patterned insulating layer covers the first patterned conductive layer and the part of the first patterned insulating layer exposed by the second opening to electrically insulate the first patterned conductive layer from the first electrode and the second patterned conductive layer.

8. The fabricating method of the pixel structure as claimed in claim 1, wherein a top diameter of the third opening is smaller than the top diameter of the second opening.

9. The fabricating method of the pixel structure as claimed in claim 1, wherein a horizontal distance between a top edge of the second opening and a top edge of the third opening is ranged from 0.01 μm to 3.0 μm.

10. The fabricating method of the pixel structure as claimed in claim 1, wherein materials of the first patterned conductive layer and the second patterned conductive layer respectively comprise a transparent conductive material.

11. The fabricating method of the pixel structure as claimed in claim 1, wherein the fabricating method of the thin film transistor comprises:
forming a gate electrode on the substrate;
forming a gate dielectric layer on the substrate, wherein the gate dielectric layer covers the gate electrode;
forming a channel layer on the gate dielectric layer substantially aligned to the gate electrode; and
forming the first electrode and a second electrode on two sides of the channel layer, wherein the first electrode and the second electrode are electrically connected to the channel layer.

12. The fabricating method of the pixel structure as claimed in claim 1, further comprising:
forming a plurality of first wires on the substrate;
forming a gate dielectric layer on the first wires;
forming a plurality of second wires on the gate dielectric layer, wherein the first wires and the second wires are alternately disposed on the substrate;
forming the first insulating layer and the first conductive layer sequentially on the second wires;
forming a plurality of first conductive pattern blocks while forming the first patterned conductive layer by the wet etching process, wherein each of the first conductive pattern blocks is correspondingly disposed above one of the second wires; and
forming a plurality of first insulating pattern blocks while forming the first patterned insulating layer by the dry etching process, wherein each of the first insulating pattern blocks is correspondingly disposed below one of the first conductive pattern blocks.

13. A pixel structure, disposed on a substrate, the pixel structure comprising:
a thin film transistor, disposed on the substrate and comprising a first electrode;
a planar layer, disposed on the substrate, wherein the planar layer has a first opening for exposing a part of the first electrode;
a first patterned conductive layer, disposed on the planar layer and filled into the first opening, the first patterned conductive layer has a second opening, wherein the second opening is located within the first opening for exposing the part of the first electrode;
a first patterned insulating layer, disposed between the substrate and the planar layer and covering the thin film transistor, wherein the first patterned insulating layer has a third opening, the third opening is smaller than the second opening, and the third opening is self-aligned within the second opening and for exposing the first electrode;
a second patterned insulating layer, disposed on the first patterned conductive layer, wherein the second patterned insulating layer covers the first patterned conductive layer and a part of the first patterned insulating layer exposed by the second opening, the second patterned insulating layer has a fourth opening, the fourth opening is located within the third opening and exposes the part of the first electrode; and
a second patterned conductive layer, wherein the second patterned conductive layer is electrically connected to the first electrode via the fourth opening.

14. The pixel structure as claimed in claim 13, wherein the first electrode comprises a drain electrode.

15. The pixel structure as claimed in claim 13, wherein the planar layer comprises an organic material layer.

16. The pixel structure as claimed in claim 13, wherein the first opening has a first bottom diameter, the second opening has a second bottom diameter, and the second bottom diameter is larger than or equal to the first bottom diameter.

17. The pixel structure as claimed in claim 13, wherein a horizontal distance between a top edge of the first opening and a top edge of the second opening is ranged from 0.01 μm to 10 μm.

18. The pixel structure as claimed in claim 13, wherein the second patterned insulating layer covers the first patterned conductive layer and the part of the first patterned insulating layer exposed by the second opening to electrically insulate the first patterned conductive layer from the first electrode and the second patterned conductive layer.

19. The pixel structure as claimed in claim 13, wherein a top diameter of the third opening is substantially smaller than a top diameter of the second opening.

20. The pixel structure as claimed in claim 13, wherein a horizontal distance between a top edge of the second opening and a top edge of the third opening is ranged from 0.01 μm to 3.0 μm.

21. The pixel structure as claimed in claim 13, wherein materials of the first patterned conductive layer and the second patterned conductive layer respectively comprise a transparent conductive material.

22. The pixel structure as claimed in claim 13, wherein the thin film transistor comprises:
a gate electrode, disposed on the substrate;
a gate dielectric layer, disposed on the substrate and covering the gate electrode;
a channel layer, disposed on the gate dielectric layer and aligned to the gate electrode; and
the first electrode and a second electrode, disposed on two sides of the channel layer and electrically connected to the channel layer.

23. The pixel structure as claimed in claim 13, further comprising:
a plurality of first wires, disposed on the substrate;
a gate dielectric layer, disposed on the first wires and covering the first wires;
a plurality of second wires, disposed on the gate dielectric layer, wherein the first wires and the second wires are alternately disposed on the substrate;
a plurality of first insulating pattern blocks, wherein each of the first insulating pattern blocks is disposed on one of the second wires; and
a plurality of first conductive pattern blocks, wherein each of the first conductive pattern blocks is disposed on one of the first insulating pattern blocks.

24. The pixel structure as claimed in claim 23, wherein the first conductive pattern blocks and the first patterned conductive layer are made of the same layer.

25. The pixel structure as claimed in claim 23, wherein the first insulating pattern blocks and the first patterned insulating layer are made of the same layer.
